(19) United States
(12) Patent Application Publication
(10) Pub. No.: US 2023/0059274 A1
(43) Pub. Date: Feb. 23, 2023

(54) GLASS COMPOSITION AND SEALING MATERIAL

(71) Applicant: Nippon Electric Glass Co., Ltd., Shiga (JP)

(72) Inventor: Shoichi SANO, Shiga (JP)

(21) Appl. No.: 17/795,287

(22) PCT Filed: Jan. 26, 2021
(86) PCT No.: PCT/JP2021/002641

§ 371 Date: Jul. 26, 2022

(30) Foreign Application Priority Data
Feb. 18, 2020 (JP) 2020-025022
May 15, 2020 (JP) 2020-085891

(51) Int. Cl. C03C 8/08; C03C 3/12; C03C 8/16

(52) U.S. Cl. CPC C03C 8/08; C03C 3/127; C03C 3/122; C03C 8/16

(57) ABSTRACT

Provided are a glass composition capable of sealing through low-temperature firing without containing environmentally harmful lead, and a sealing material using the same. The glass composition includes, in terms of mol %, 1%, to 30% of MgO+CaO+SrO+BaO+ZnO, 30% to 80% of TeO₂, and 5% to 30% of MoO₃.

### TECHNICAL FIELD

The present invention relates to a glass composition capable of airtight sealing through low-temperature firing without containing harmful lead and while having weather resistance, and to a sealing material using the same.

### BACKGROUND ART

A sealing material is used for, for example, a semiconductor integrated circuit, a crystal oscillator, a metal member, a flat display apparatus, and a glass terminal for LED use.

The sealing material is required to have chemical durability and heat resistance, and hence a glass-based sealing material has been used instead of a resin-based adhesive. The sealing material is further required to have characteristics, such as mechanical strength, flowability, and weather resistance, but sealing of an electronic part mounted with an element that is vulnerable to heat is required to be performed at as low a sealing temperature as possible. Specifically, sealing at 400° C. or less is preferred. Accordingly, as glass that satisfies the above-mentioned characteristics, there has been widely used lead borate-based glass containing a large amount of PbO, which has an extremely large effect of reducing a softening point (see, for example, Patent Literature 1).

### CITATION LIST

Patent Literature 1: JP 63-315536 A
Patent Literature 2: JP 2019-202921 A

### SUMMARY OF INVENTION

### Technical Problem

An environmental problem has been pointed out with PbO contained in the lead borate-based glass, and it is desired that the lead borate-based glass be replaced by PbO-free glass. For that purpose, various low-softening-point glasses have been developed as alternatives to the lead borate-based glass. However, in general, as the softening point of glass becomes lower, the weather resistance of the glass tends to be degraded, and hence there is a technical problem of how to strike a balance therebetween. CuO—TeO₂—MoO₃—based glass described in Patent Literature 2 has been promising as a candidate alternative to the lead borate-based glass, but has been required to achieve a further reduction in sealing temperature in consideration of the heat resistance of the element described above, though having weather resistance.

In view of the foregoing, an object of the present invention is to provide a glass composition capable of sealing through low-temperature firing while having weather resistance, and a sealing material using the same.

### Solution to Problem

According to one embodiment of the present invention, there is provided a glass composition, comprising, in terms of to 30% of MgO+CaO+SrO+BaO+ZnO, 30% to 80% of TeO₂, and 5% to 30% of MoO₃. Herein, the “MgO+CaO+SrO+BaO+ZnO” means the total content of MgO, CaO, SrO, BaO, and ZnO.

The glass composition of the present invention achieves a low softening point, while having the weather resistance of glass, by virtue of setting the total content of MgO, CaO, SrO, BaO, and ZnO to 11 or more. In general, as the softening point of glass becomes lower, there is a tendency that vitrification is difficult or phase separation occurs, with the result that homogeneous glass is difficult to obtain. However, in the present invention, by virtue of specifying that the content of TeO₂ is 30% or more and the content of MoO₃ is 5% or more, the glass is stabilized, and hence homogeneous glass can be obtained.

Further, the glass composition according to the one embodiment of the present invention preferably comprises, in terms of mol %, 1% to 30%, of Li₂O+Na₂+K₂O. Herein, the “Li₂O+Na₂O+K₂O” means the total content of Li₂O, Na₂O, and K₂O.

Further, the glass composition according to the one embodiment of the present invention preferably comprises, in terms of mol %, 1%, to 30% of BaO.

Further, the glass composition according to the one embodiment of the present invention preferably comprises, in terms of mol %, 0% to 10%, of TiO₂+Al₂O₃. Herein, the “TiO₂+Al₂O₃”means the total content of TiO₂ and Al₂O₃.

Further, the glass composition according to the one embodiment of the present invention preferably comprises, in terms of mol %, 1% to 10% of Al₂O₃.

Further, the glass composition according to the one embodiment of the present invention preferably comprises, in terms of mol %, 0% to 30% of CuO, 0% to 20% of WO₃, and 0% to 10% of P₂O₅.

Further, the glass composition according to the one embodiment of the present invention preferably comprises, in terms of mol %, 1% to 30% of CuO.

According to one embodiment of the present invention, there is provided a sealing material, comprising: 90 vol % to 100 vol % of glass powder formed of the above-mentioned glass composition; and 0 vol % to 60 vol % of refractory filler powder.

In the sealing material according to the one embodiment of the present invention, the refractory filler powder preferably contains Zr₂WO₄ (PO₄)₂.

In the sealing material according to the one embodiment of the present invention, the refractory filler powder preferably has an approximately spherical shape.

The sealing material according to the one embodiment of the present invention is preferably used for a crystal oscillator package.

According to one embodiment of the present invention, there is provided a sealing material paste, comprising: the above-mentioned sealing material; and a vehicle.

### Advantageous Effects of Invention

The present invention can provide the glass composition capable of sealing through low-temperature firing without containing environmentally harmful lead, and the sealing material using the same.

### BRIEF DESCRIPTION OF DRAWINGS

FIG. 1 is a schematic diagram for illustrating a measured curve obtained with a macro-type differential thermal analyzer.

### DESCRIPTION OF EMBODIMENTS

A glass composition of the present invention comprises, in terms of mol %, 1% to 30% of MgO+CaO+SrO+BaO+ZnO, 30% to 80% of TeO₂, and 5% to 30% of MoO₃. Reasons why the glass composition is limited as described above are described below. In the following description concerning the content of each component, “7.” means “mol %” unless otherwise Stated.

MgO, CaO, SrO, BaO, and ZnO are each a component that broadens a vitrification range and improves the weather resistance of glass. MgO+CaO+SrO+BaO+ZnO is from 1% to 30%, preferably from 3% to 25%, more preferably from 5% to 20%, still more preferably from 8% to 18%, particularly preferably from 10% to 15%. When MgO+CaO+SrO+BaO+ZnO is excessively small, vitrification becomes difficult. In addition, the weather resistance of the glass is degraded. Besides, the glass becomes thermally unstable, and hence the glass becomes liable to devitrify at the time of melting or at the time of firing. Meanwhile, also when MgO+CaO+SrO+BaO+ZnO is excessively large, the glass becomes thermally unstable, and hence the glass becomes liable to devitrify at the time of melting or at the time of firing.

Preferred ranges of the contents of MgO, CaO, SrO, BaO, and ZnO are as described below.

MgO is a component that broadens the vitrification range and improves the weather resistance of the glass while suppressing an excessive increase in softening point of the glass. The content of MgO is from 1% to 30%, preferably from 3% to 25%, more preferably from 5% to 20%, still more preferably from 8% to 18%, particularly preferably from 10% to 15%. When the content of MgO is excessively small, vitrification becomes difficult, and the weather resistance of the glass is degraded. Besides, the glass becomes thermally unstable, and hence the glass becomes liable to devitrify at the time of melting or at the time of firing. Meanwhile, also when the content of MgO is excessively large, the glass becomes thermally unstable, and hence the glass becomes liable to devitrify at the time of melting or at the time of firing.

CaO is a component that broadens the vitrification range and improves the weather resistance of the glass while suppressing an excessive increase in softening point of the glass. The content of CaO is from 1% to 30%, preferably from 3% to 25%, more preferably from 5% to 20%, still more preferably from 8% to 18%, particularly preferably from 10% to 15%. When the content of CaO is excessively small, vitrification becomes difficult, and the weather resistance of the glass is degraded. Besides, the glass becomes thermally unstable, and hence the glass becomes liable to devitrify at the time of melting or at the time of firing. Meanwhile, also when the content of CaO is excessively large, the glass becomes thermally unstable, and hence the glass becomes liable to devitrify at the time of melting or at the time of firing.

SrO is a component that broadens the vitrification range and improves the weather resistance of the glass while suppressing an excessive increase in softening point of the glass. The content of SrO is from 1% to 30%, preferably from 3% to 25%, more preferably from 5% to 20%, still more preferably from 8% to 18%, particularly preferably from 10% to 15%. When the content of SrO is excessively small, vitrification becomes difficult, and the weather resistance of the glass is degraded. Besides, the glass becomes thermally unstable, and hence the glass becomes liable to devitrify at the time of melting or at the time of firing. Meanwhile, also when the content of SrO is excessively large, the glass becomes thermally unstable, and hence the glass becomes liable to devitrify at the time of melting or at the time of firing.

BaO is a component that, as compared to MgO, CaO, SrO, and ZnO, remarkably broadens the vitrification range, remarkably reduces the softening point of the glass, and remarkably improves the weather resistance of the glass. The content of BaO is from 1% to 30%, preferably from 3% to 25%, more preferably from 5% to 20%, still more preferably from 8% to 18%, particularly preferably from 10% to 15%. When the content of BaO is excessively small, vitrification becomes difficult, and low-temperature sealing becomes difficult because the softening point is not reduced. Besides, the glass becomes thermally unstable, and hence the glass becomes liable to devitrify at the time of melting or at the time of firing. In addition, it becomes difficult to maintain the weather resistance of the glass. Meanwhile, also when the content of BaO is excessively large, the glass becomes thermally unstable, and hence the glass becomes liable to devitrify at the time of melting or at the time of firing.

ZnO is a component that broadens the vitrification range and improves the weather resistance of the glass while suppressing an excessive increase in softening point of the glass. The content of ZnO is from 1% to 30%, preferably from 3% to 25%, more preferably from 5% to 20%, still more preferably from 8% to 18%, particularly preferably from 10% to 15%. When the content of ZnO is excessively small, vitrification becomes difficult, and the weather resistance of the glass is degraded. Besides, the glass becomes thermally unstable, and hence the glass becomes liable to devitrify at the time of melting or at the time of firing. Meanwhile, also when the content of ZnO is excessively large, the glass becomes thermally unstable, and hence the glass becomes liable to devitrify at the time of melting or at the time of firing.

TeO₂ is a component that forms a glass network, and besides, improves the weather resistance. The content of TeO₂ is from 30% to 80%, preferably from 35%, to 75%, more preferably from 40% to 70%, still more preferably from 45% to 65%, particularly preferably from 50% to 60%. When the content of TeO₂ is excessively small, the glass becomes thermally unstable, and hence the glass becomes liable to devitrify at the time of melting or at the time of firing. Besides, the weather resistance becomes liable to be lowered. Meanwhile, when the content of TeO₂ is excessively large, the viscosity (softening point or the like) of the glass is increased to make low-temperature sealing difficult. Besides, the glass becomes thermally unstable, and hence the glass becomes liable to devitrify at the time of melting or at the time of firing. In addition, the thermal expansion coefficient of the glass tends to be increased excessively.

MoO₃ is a component that forms a glass network, and besides, improves the weather resistance. The content of MoO₃ is from 5% to 30%, preferably from 7% to 27% more preferably from 10% to 25%, still more preferably from 12% to particularly preferably from 15% to 20%. When the content of MoO₃ is excessively small, the glass becomes thermally unstable, and hence the glass becomes liable to devitrify at the time of melting or at the time of firing. Besides, the viscosity (softening point or the like) of the glass is increased to make low-temperature sealing difficult. Meanwhile, when the content of MoO₃ is excessively large, vitrification becomes difficult. In addition, the glass becomes thermally unstable, and hence the glass becomes liable to devitrify at the time of melting or at the time of firing. Besides, the thermal expansion coefficient of the glass tends to be increased excessively.

The glass composition of the present invention may comprise the following components in its glass composition in addition to the above-mentioned components.

Li₂O, Na₂O, and K₂O are each a component that lowers the viscosity (softening point or the like) of the glass. Li₂O+Na₂O+K₂O is preferably from 1% to 30%, more preferably from 2% to 25%, still more preferably from 5% to 20%, particularly preferably from 8% to 15%. When Li₂O+Na₂O+K₂O is excessively small, the viscosity (softening point or the like) of the glass is increased to make low-temperature sealing difficult. Besides, the glass becomes thermally unstable, and hence the glass becomes liable to devitrify at the time of melting or at the time of firing. Meanwhile, when Li₂O+Na₂O+K₂O is excessively large, the glass becomes thermally unstable, and hence the glass becomes liable to devitrify at the time of melting or at the time of firing.

Li₂O is a component that, as compared to Na₂O and K₂O, remarkably lowers the viscosity (softening point or the like) of the glass. The content of Li₂O is preferably from to 30%, more preferably from 2% to 25%, still more preferably from 3% to 20%, particularly preferably from 5% to 18%. When the content of Li₂O is excessively small, the viscosity (softening point or the like) of the glass is increased to make low-temperature sealing difficult. Meanwhile, when the content of Li₂O is excessively large, the glass becomes thermally unstable, and hence the glass becomes liable to devitrify at the time of melting or at the time of firing.

Na₂O is a component that, as compared to K₂O, lowers the viscosity (softening point or the like) of the glass. The content of Na₂O is preferably from 1% to 20%, more preferably from 2% to 15%, still more preferably from 3% to 12%, particularly preferably from 5% to 10%. When the content of Na₂O is excessively small, the viscosity (softening point or the like) of the glass is increased to make low-temperature sealing difficult. Meanwhile, when the content of Na₂O is excessively large, the glass becomes thermally unstable, and hence the glass becomes liable to devitrify at the time of melting or at the time of firing.

K₂O is a component that lowers the viscosity (softening point or the like) of the glass. The content of K₂O is preferably from 1%, to 30%, more preferably from 2% to 25%, still more preferably from 3% to 20%, particularly preferably from 5% to 18%. When the content of K₂O is excessively small, the viscosity (softening point or the like) of the glass is increased to make low-temperature sealing difficult. Meanwhile, when the content of K₂O is excessively large, the glass becomes thermally unstable, and hence the glass becomes liable to devitrify at the time of melting or at the time of firing.

Further, in order to lower the softening point of the glass through an alkali mixing effect, a molar ratio Li₂O/K₂O is preferably from 0.3% to 5, more preferably from 0.4% to 4 or from 0.5% to 3, still more preferably from 0.6% to 2, particularly preferably from 0.7% to 1.5. When Li₂O/K₂O is excessively small, the viscosity (softening point or the like) of the glass is increased to make low-temperature sealing difficult. Besides, the glass becomes thermally unstable, and hence the glass becomes liable to devitrify at the time of melting or at the time of firing. Meanwhile, when Li₂O/K₂O is excessively large, the glass becomes thermally unstable, and hence the glass becomes liable to devitrify at the time of melting or at the time of firing.

TiO₂ and Al₂O₃ are each a component that improves the weather resistance. TiO₂+Al₂O₃ is preferably from 0% to 10%, more preferably from 0.1% to 8%, still more preferably from 1% to 6% particularly preferably from 2% to 5%. When TiO₂+Al₂O₃, is excessively large, the viscosity (softening point or the like) of the glass is increased to make low-temperature sealing difficult. Besides, the glass becomes thermally unstable, and hence the glass becomes liable to devitrify at the time of melting or at the time of firing.

Preferred ranges of the contents of TiO₂ and Al₂O₃ are as described below.

The content of TiO₂ is preferably from 0% to 8%, more preferably from 0.1% to 6%, still more preferably from 1% to 5%, particularly preferably from 2% to 4%. The content of Al₂O₃ is preferably from 0% to 8%, more preferably from 0.1% to 5%, still more preferably from 0.5% to 3%, particularly preferably from 1% to 2%.

CuO is a component that lowers the viscosity (softening point or the like) of the glass, and besides, lowers the thermal expansion coefficient of the glass. In addition, in the case of sealing a metal, CuO is a component that improves adhesive strength between the glass and the metal. Details of the mechanism thereof are unknown at present, but a conceivable reason is as follows: Cu atoms have high diffusibility, and hence Cu atoms diffuse from the surface layer of the metal toward the inside thereof to facilitate integration between the glass and the metal. The kind of the metal to be sealed is not particularly limited, but examples thereof include iron, an iron alloy, nickel, a nickel alloy, copper, a copper alloy, aluminum, and an aluminum alloy. The content of CuO is preferably from 0% to 30%, from 0% to 10%, from 0.1% to 5%, or from 0.5%, to 3%, particularly preferably from 1% to 2%. In addition, the content of CuO in the case of sealing a metal is preferably from 1% to 30%, more preferably from 1% to 20%, still more preferably from 3% to 15%, particularly preferably from 5% to 10% When the content of CuO is excessively large, the glass becomes thermally unstable, and there is a risk in that, in a sealing process, metal Cu may be precipitated from the surface of the glass to adversely affect a sealing property and electrical characteristics. In addition, the glass becomes liable to devitrify at the time of melting or at the time of firing.

WO₃ is a component that lowers the thermal expansion coefficient of the glass. The content of WO₃ is from 0% to 20% or from 0.1% to 10%, particularly from 1% to 5%. When the content of WO₃ is excessively large, the glass becomes thermally unstable, and hence the glass becomes liable to devitrify at the time of melting or at the time of firing. Besides, the viscosity (softening point or the like) of the glass is increased to make low-temperature sealing difficult.

P₂O₅, is a component that forms a glass network, and besides, thermally stabilizes the glass. The content of P₂O₅ is preferably from 0% to 10%, more preferably from 0.1% to 5%, still more preferably from 0.2% to 2%, particularly preferably from 0.5% to 1%. When the content of P₂O₅, is excessively large, the viscosity (softening point or the like) of the glass is increased to make low-temperature Sealing difficult, and besides, the weather resistance becomes liable to be lowered.

Ag₂O is a component that lowers the viscosity (softening point or the like) of the glass. The content of Ag₂O is preferably from 0% to 10%, more preferably from 0.1%, to 5%, still more preferably from 0.2% to 3%, particularly preferably from 0.5% to 2%. When the content of Ag₂O is excessively large, the glass becomes thermally unstable, and hence the glass becomes liable to devitrify at the time of melting or at the time of firing. In addition, there is a risk in that metal Ag may be precipitated in the glass owing to a firing atmosphere.

AgI is a component that lowers the viscosity (softening point or the like) of the glass. The content of AgI is preferably from 0%, to 10%, more preferably from 0.1% to 5%, still more preferably from 0.2% to 2%, particularly preferably from 0.5% to 1%. When the content of AgI is excessively large, the thermal expansion coefficient of the glass tends to be increased excessively.

Nb₂O₅, is a component that thermally stabilizes the glass, and besides, improves the weather resistance. The content of Nb₂O₅ is preferably from 0% to 10%, more preferably from 0.1% to 5%, still more preferably from 0.2% to 2%, particularly preferably from 0.5%, to 1%. When the content of Nb₂O₅ is excessively large, the viscosity (softening point or the like) of the glass is increased, and hence low-temperature sealing becomes liable to be difficult.

V₂O₅, is a component that forms a glass network, and besides, lowers the viscosity (softening point or the like) of the glass. The content of V₂O₅, is preferably from 0% to 10%, more preferably from 0.1% to 5%, still more preferably from 0.2% to 3%, yet still more preferably from 1% to 2%. When the content of V₂O₅ is excessively large, the glass becomes thermally unstable, and hence the glass becomes liable to devitrify at the time of melting or at the time of firing. Besides, the weather resistance becomes liable to be lowered.

Ga₂O₃ is a component that thermally stabilizes the glass, and besides, improves the weather resistance. However, Ga₂O₃ is extremely expensive, and hence its content is preferably less than 0.01%, and it is particularly preferred that the glass composition be free of Ga₂O₃.

SiO₂, GeO₂, Fe₂O₃, NiO, CeO₂, B₂O₃, Sb₂O₃, and ZrO₂ are each a component that thermally stabilizes the glass to suppress devitrification, and may each be added at up to less than 2% When their contents are excessively large, the glass becomes thermally unstable, and hence the glass becomes liable to devitrify at the time of melting or at the time of firing.

It is preferred for an environmental reason that the glass composition of the present invention be substantially free of PbO. As used herein, the expression “substantially free of PbO” refers to a case in which the content of PbO in the glass composition is 1% or less.

A sealing material of the present invention comprises glass powder formed of the above-mentioned glass composition. The sealing material of the present invention may comprise refractory filler powder in order to improve its mechanical strength or adjust its thermal expansion coefficient. Their mixing ratios are preferably 40 vol % to 100 vol % of the glass powder and 0 vol % to 60 vol % of the refractory filler powder, more preferably 50 vol % to 99 vol % of the glass powder and 1 vol % to 50 vol % of the refractory filler powder, still more preferably 60 vol % to 95 vol % of the glass powder and 5 vol % to 40 vol % of the refractory filler powder, particularly preferably 70 vol % to 90 vol % of the glass powder and 10 vol % to 30 vol % of the refractory filler powder. When the content of the refractory filler powder is excessively large, the ratio of the glass powder is relatively reduced, and hence it becomes difficult to secure desired flowability.

The refractory filler powder preferably contains Zr₂WO₄ (PO₄)₂. Zr₂WO₄ (PO₄)₂ hardly reacts with the glass powder, and can efficiently lower the thermal expansion coefficient of the sealing material.

In addition, the sealing material of the present invention may use, as the refractory filler powder, refractory filler powder other than Zr₂WO₄(PO₄)₂. As the other refractory filler powder, powders formed of, for example, NbZr(PO₄)₃, Zr₂MoO₄ (PO₄)₂, Hf₂WO₄ (PO₄)₂, Hf₂MoO₄(PO₄)₂, zirconium phosphate, zircon, zirconia, tin oxide, aluminum titanate, quartz, β-spodumene, mullite, titanic, quartz glass, β-eucryptite, β-quartz, willemite, cordierite, and Sr_{0.5}Zr₂(PO₄)₃ may be used alone or as a mixture thereof.

The refractory filler powder preferably has an approximately spherical shape. With such configuration, at the time of the softening of the glass powder, the flowability of the glass powder is hardly inhibited by the refractory filler powder, and as a result, the flowability of the sealing material is improved. In addition, a smooth glaze layer can be easily obtained. Further, even if part of the refractory filler powder is exposed on the surface of the glaze layer, by virtue of the refractory filler powder having an approximately spherical shape, a stress in this portion is dispersed, and moreover, even when an object to be sealed is brought into abutment with the glaze layer at the time of sealing, an improper stress is hardly applied to the object to be sealed, and as a result, airtightness can be easily secured. The term “approximately spherical shape” as used in the present invention is not limited only to a true sphere, and refers to such a shape that a value obtained by dividing the shortest diameter of the refractory filler powder passing through the center of gravity of the refractory filler powder by the longest diameter is 0.5 or more, preferably 0.7 or more.

With regard to the particle diameter of the refractory filler powder, refractory filler powder having an average particle diameter D₅₀ of from about 0.2 μm to about 20 μm is preferably used.

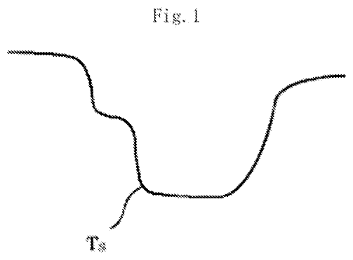

The softening point of the sealing material of the present invention is preferably 350° C. or less, particularly preferably 340° C. or less. When the softening point is excessively high, the viscosity of the glass is increased, and hence a sealing temperature is increased to satisfy predetermined flowability, resulting in a risk of deteriorating an element due to heat at the time of sealing. The lower limit of the softening point is not particularly limited, but is practically 180° C. or more. Herein, the “softening point” refers to a value measured with a macro-type differential thermal analyzer using a sealing material having an average particle diameter D₅₀ of from 0.5 μm to 20 μm as a measurement sample. With regard to measurement conditions, the measurement is started at room temperature, and a temperature increase rate is set to 10° C./min. The softening point measured with the macro-type differential thermal analyzer refers to the temperature (Ts) at the fourth inflection point in a measured curve illustrated in FIG. 1.

The thermal expansion coefficient (30° C. to 150° C.) of the sealing material of the present invention is preferably from 20×10⁻⁷/° C. to 200λ10⁻⁷/° C., more preferably from 30×10⁻⁷/° C. to 160×10⁻⁷/° C., still more preferably from 40×10⁻⁷/° C. to 140×10⁻/° C., particularly preferably from 50×10⁻/° C. to 120×10⁻⁷/° C. When the thermal expansion coefficient is excessively low or excessively high, owing to a difference in thermal expansion with a material to be sealed, a sealed portion becomes liable to be broken at the time of sealing or after sealing.

The sealing material of the present invention having the above-mentioned characteristics is suitable for a crystal oscillator package, which requires sealing at a particularly low temperature.

Next, examples of a method of producing glass powder involving using the glass composition of the present invention, and a method of using the glass composition of the present invention as a sealing material are described.

First, raw material powder blended so as to achieve the above-mentioned composition is melted at from 800° C. to 1,000° C. for from 1 hour to 2 hours until homogeneous glass is obtained. Then, the molten glass is formed into a film shape or the like, and then the resultant is pulverized and classified to produce glass powder formed of the glass composition of the present invention. The average particle diameter D₅₀ of the glass powder is preferably from about 1 μm to about 20 μm. A sealing material is obtained by adding any of various refractory filler powders to the glass powder as required.

Then, a vehicle is added to and kneaded with the glass powder (or sealing material) to prepare a glass paste (or sealing material paste). The vehicle is formed mainly of an organic solvent and a resin, and the resin is added for the purpose of adjusting the viscosity of the paste. In addition, as required, a surfactant, a thickener, or the like may also be added.

The organic Solvent is preferably an organic solvent that has a low boiling point (e.g., a boiling point of 300° C. or less), leaves little residue after firing, and does not alter the glass, and its content is preferably from 10 mass % to 40 mass %. As the organic solvent, propylene carbonate, toluene, N,N′-dimethylformamide (DMF), 1,3-dimethyl-2-imidazolidinone (DMI), dimethyl carbonate, butyl carbitol acetate (BCA), isoamyl acetate, dimethyl sulfoxide, acetone, methyl ethyl ketone, or the like is preferably used. In addition, as the organic solvent, a higher alcohol is more preferably used. The higher alcohol itself has viscosity, and hence enables the formation of a paste without adding a resin to the vehicle. In addition, pentanediol and a derivative thereof, specifically diethylpentanediol (C₂H₂₀O₂), are also excellent in viscosity, and hence may each be used as the solvent.

The resin is preferably a resin that has a low decomposition temperature, leaves little residue after firing, and hardly alters the glass, and its content is preferably from 0.1 mass % to 20 mass %. As the resin, nitrocellulose, a polyethylene glycol derivative, polyethylene carbonate, an acrylic acid ester (acrylic resin), or the like is preferably used.

Then, the glass paste (sealing material paste) is applied to a sealing portion of an object to be sealed that is formed of a metal, ceramic, or glass through use of an applicator, such as a dispenser or a screen printing machine, and is dried and subjected to glazing treatment at from 300° C. to 350° C. After that, under a state in which the object to be sealed is brought into contact with the glass powder, heat treatment is performed at from 350° C. to 400° C., and thus the glass powder softens and flows to achieve sealing therebetween.

The glass composition of the present invention may be used for the purpose of, for example, coating or filling besides the sealing application. In addition, the glass composition of the present invention may also be used in a form other than a paste, specifically in the state of, for example, powder, a green sheet, or a tablet (press frit that is a sintered body of powder).

### EXAMPLES

The present invention is described in detail by way of Examples. Examples of the present invention (Samples Nos. 1 to 17) and Comparative Examples (Samples Nos. 18 to 21) are shown in Tables 1 and 2.

TABLE 1

| | | No. 1 | No. 2 | No. 3 | No. 4 | No. 5 | No. 6 |
|---|---|---|---|---|---|---|---|
| Glass | MgO | 3 | | | 2 | | |
| composition | CaO | | 2 | | | | |
| (mol %) | SrO | | 3 | | | 2.5 | |
| | BaO | 3 | 22 | 2 | 12 | 1.5 | 5 |
| | ZnO | | | | | | |
| | TeO₂ | 65 | 35 | 74 | 54 | 68 | 60 |
| | MoO₃ | 10 | 17 | 10 | 10 | 10 | 10 |
| | Li₂O | 8 | 9 | 5 | 8 | 9 | 25 |
| | Na₂O | | | | | | |
| | K₂O | 8 | 9 | 5 | 8 | 9 | |
| | TiO₂ | | 1 | | | | |
| | Al₂O₃ | 3 | 2 | 4 | 6 | | |
| | CuO | | | | | | |
| | WO₃ | | | | | | |
| | P₂O₅ | | | | | | |
| | MgO + CaO + SrO + | 6 | 27 | 2 | 14 | 4 | 5 |
| | BaO + ZnO | | | | | | |
| | Li₂O + Na₂O + K₂O | 16 | 18 | 10 | 16 | 18 | 25 |
| | Li₂O/K₂O | 1.0 | 1.0 | 1.0 | 1.0 | 1.0 | |
| | TiO₂ + Al₂O₃ | 3 | 3 | 4 | 6 | 0 | 0 |

| | | | | | | |
|---|---|---|---|---|---|---|
| Glass powder (vol %) | 80 | 85 | 80 | 90 | 80 | 80 |
| Refractory filler powder (vol %) | ZWP | ZWP | ZWP | ZWP | ZWP | ZWP |
| | 20 | 15 | 20 | 10 | 20 | 20 |
| Glass transition point (° C.) | 285 | 292 | 286 | 295 | 258 | 252 |
| Thermal expansion coefficient | 74 | 84 | 70 | 80 | 76 | 79 |
| (×10⁻⁷/° C.) | | | | | | |
| Softening point (° C.) | 340 | 347 | 345 | 348 | 317 | 312 |
| Flowability | ∘ | ∘ | ∘ | ∘ | ∘ | ∘ |
| Devitrification | Absent | Absent | Absent | Absent | Absent | Absent |
| Weather resistance | ∘ | ∘ | ∘ | ∘ | ∘ | ∘ |
| Adhesiveness to metal | Unevaluated | Unevaluated | Unevaluated | Unevaluated | Unevaluated | Unevaluated |

| | | No. 7 | No. 8 | No. 9 | No. 10 |
|---|---|---|---|---|---|
| Glass | MgO | | | | |
| composition | CaO | | | | |
| (mol %) | SrO | | 6 | 2 | |
| | BaO | 4 | 9 | 18 | 3 |
| | ZnO | | | 2.5 | |
| | TeO₂ | 64 | 62.5 | 45.5 | 70 |
| | MoO₃ | 10 | 22.5 | 14 | 10 |
| | Li₂O | 9 | | 8 | 6 |
| | Na₂O | | | | |
| | K₂O | 9 | | 6 | 10 |
| | TiO₂ | | | 2 | |
| | Al₂O₃ | 4 | | 2 | 1 |
| | CuO | | | | |
| | WO₃ | | | | |
| | P₂O₅ | | | | |
| | MgO + CaO + SrO + | 4 | 15 | 22.5 | 3 |
| | BaO + ZnO | | | | |
| | Li₂O + Na₂O + K₂O | 18 | 0 | 14 | 16 |
| | Li₂O/K₂O | 1.0 | | 1.3 | 0.6 |
| | TiO₂ + Al₂O₃ | 4 | 0 | 4 | 1 |

| | | | | |
|---|---|---|---|---|
| Glass powder (vol %) | 80 | 70 | 80 | 70 |
| Refractory filler powder (vol %) | ZWP | ZWP | ZWP | ZWP |
| | 20 | 30 | 20 | 30 |
| Glass transition point (° C.) | 281 | 278 | 298 | 282 |
| Thermal expansion coefficient | 73 | 66 | 69 | 67 |
| (×10⁻⁷/° C.) | | | | |
| Softening point (° C.) | 340 | 350 | 348 | 335 |
| Flowability | ∘ | ∘ | ∘ | ∘ |
| Devitrification | Absent | Absent | Absent | Absent |
| Weather resistance | ∘ | ∘ | ∘ | ∘ |
| Adhesiveness to metal | Unevaluated | Unevaluated | Unevaluated | Unevaluated |

TABLE 2

| | | No. 11 | No. 12 | No. 13 | No. 14 | No. 15 | No. 16 |
|---|---|---|---|---|---|---|---|
| Glass | MgO | 2 | | | | | |
| composition | CaO | | | | | | |
| (mol %) | SrO | | 3 | | 1 | 2 | |
| | BaO | 2 | | 2 | 4 | 2 | 4 |
| | ZnO | | | 4 | | | |
| | TeO₂ | 64 | 60 | 65 | 61 | 47 | 59 |
| | MoO₃ | 9 | 5 | 13 | 7 | 25 | 9 |
| | Li₂O | 8 | 22 | 7 | 10 | 11 | 9 |
| | Na₂O | | | | | 3 | |
| | K₂O | 8 | | 7 | 10 | 5 | 9 |
| | TiO₂ | 1 | | | 2 | 5 | |
| | Al₂O₁ | 2 | 5 | 2 | | | 4 |
| | CuO | | 5 | | | | 6 |
| | WO₃ | 4 | | | | | |
| | P₂O₅ | | | | 5 | | |
| | MgO + CaO + SrO + | 4 | 3 | 6 | 5 | 4 | 4 |
| | BaO + ZnO | | | | | | |
| | Li₂O + Na₂O + K₂O | 16 | 22 | 14 | 20 | 19 | 18 |
| | Li₂O/K₂O | 1.0 | | 1.0 | 1.0 | 2.2 | 1.0 |
| | TiO₂ + Al₂O₃ | 3 | 5 | 2 | 2 | 5 | 4 |

| | | | | | | |
|---|---|---|---|---|---|---|
| Glass powder (vol %) | 80 | 55 | 80 | 60 | 80 | 100 |
| Refractory filler powder (vol %) | ZWP | NZP | ZWP | NZP | ZWP | 0 |
| | 20 | 45 | 20 | 40 | 20 | |
| Glass transition point (° C.) | 299 | 285 | 284 | 275 | 280 | Unmeasured |
| Thermal expansion coefficient | 72 | 72 | 72 | 75 | 74 | Unmeasured |
| (×10⁻⁷/° C.) | | | | | | |
| Softening point (° C.) | 349 | 339 | 340 | 331 | 333 | Unmeasured |
| Flowability | ∘ | ∘ | ∘ | ∘ | ∘ | ∘ |
| Devitrification | Absent | Absent | Absent | Absent | Absent | Absent |
| Weather resistance | ∘ | ∘ | ∘ | ∘ | ∘ | ∘ |
| Adhesiveness to metal | Unevaluated | Unevaluated | Unevaluated | Unevaluated | Unevaluated | ∘ |

| | | No. 17 | No. 18 | No. 19 | No. 20 | No. 21 |
|---|---|---|---|---|---|---|
| Glass | MgO | | 10.5 | 3 | | |
| composition | CaO | | 7 | 5 | | |
| (mol %) | SrO | | | | | |
| | BaO | 6 | 0.5 | | | |
| | ZnO | 10 | 19 | | | |
| | TeO₂ | 55 | 55 | 40 | 67 | 65 |
| | MoO₃ | 11 | 8 | 38 | 23 | 25 |
| | Li₂O | 6 | | 1 | 5 | 7 |
| | Na₂O | | | | 2 | |
| | K₂O | 4 | | 1 | 3 | 3 |
| | TiO₂ | | | 4 | | |
| | Al₂O₁ | 4 | | 8 | | |
| | CuO | 4 | | | | |
| | WO₃ | | | | | |
| | P₂O₅ | | | | | |
| | MgO + CaO + SrO + | 16 | 37 | 8 | 0 | 0 |
| | BaO + ZnO | | | | | |
| | Li₂O + Na₂O + K₂O | 10 | 0 | 2 | 10 | 10 |
| | Li₂O/K₂O | 1.5 | | 1.0 | 1.7 | 2.3 |
| | TiO₂ + Al₂O₃ | 4 | 0 | 12 | 0 | 0 |

| | | | | | |
|---|---|---|---|---|---|
| Glass powder (vol %) | 100 | 80 | Did not | 80 | 100 |
| Refractory filler powder (vol %) | 0 | ZWP | vitrify | ZWP | 0 |
| | | 20 | | 20 | |
| Glass transition point (° C.) | Unmeasured | 290 | | 265 | Unmeasured |
| Thermal expansion coefficient | Unmeasured | 68 | | 76 | Unmeasured |
| (×10⁻⁷/° C.) | | | | | |
| Softening point (° C.) | Unmeasured | 345 | | 322 | Unmeasured |
| Flowability | ∘ | x | | ∘ | ∘ |
| Devitrification | Absent | Present | | Absent | Absent |
| Weather resistance | ∘ | ∘ | | x | x |
| Adhesiveness to metal | ∘ | Unevaluated | | Unevaluated | x |

First, glass raw materials, such as various oxides and carbonates, were blended so as to achieve a glass composition shown in the tables to prepare a glass batch, and then the glass batch was placed in a platinum crucible and melted in air at from 800° C. to 1,000° C. for from 1 hour to 2 hours. After that, the molten glass was formed into a film shape with a water-cooling roller, the film-shaped glass was pulverized with a ball mill, and then the resultant was passed through a sieve having an aperture of 75 μm to provide glass powder having an average particle diameter D₅₀ of about 10 μm.

After that, the resultant glass powder and refractory filler powder were mixed as shown in the tables to provide mixed powder.

Zr₂WO₄(PO₄)₂ (represented by ZWP in the tables) or NbZr(PO₄). (represented by NZP in the tables) having an approximately spherical shape was used as the refractory filler powder. The average particle diameter D₅₀ of the refractory filler powder was about 10 μm.

For each of Samples Nos. 1 to 21, there were evaluated a glass transition point, a thermal expansion coefficient, a softening point, flowability, the presence or absence of devitrification, weather resistance, and adhesiveness to metal.

The glass transition point and the thermal expansion coefficient (30° C. to 150° C.) were evaluated as described below. A mixed powder sample was placed in a rod-shaped mold and press-molded, followed by firing on an alumina substrate having applied thereto a release agent at 380° C. for 10 minutes. After that, the fired body was processed into a predetermined shape and subjected to measurement with a TMA apparatus.

For the softening point, measurement was performed with a macro-type differential thermal analyzer, and the temperature at the fourth inflection point was adopted as the softening point. A measurement atmosphere was air, a temperature increase rate was set to 10° C./min, and the measurement was started at room temperature.

The flowability was evaluated as described below. A mixed powder sample having a weight corresponding to its combination density was placed in a mold having a diameter of 20 mm and press-molded, followed by firing on a glass substrate at 380° C. for 10 minutes. A case in which the flow diameter of the fired body was 19 mm or more was marked with Symbol “o”, and a case in which the flow diameter was less than 19 mm was marked with Symbol “x”.

The presence or absence of devitrification was evaluated as described below. The surface of the fired body produced in the foregoing was visually observed. In a case in which there was no glass gloss, it was judged that devitrification was “present”, and in any other case, it was judged that devitrification was “absent”.

The weather resistance was evaluated by an accelerated aging test based on a Pressure Cooker Test (PCT). Specifically, the fired body produced in the foregoing was kept under an environment of 121° C., 2 atm, and a relative humidity of 100%, for 24 hours, and then a case in which no precipitate from the surface of the fired body was found in visual observation was marked with Symbol “o”, and any other case was marked with Symbol “x”.

The adhesiveness to metal was evaluated as described below. A glass powder sample having a weight corresponding to its density was placed in a mold having a diameter of 20 mm and press-molded, followed by firing on a stainless steel SUS304 substrate at 380° C. for 10 minutes in a nitrogen atmosphere. After the firing, the surface of SUS304 on the opposite side to its surface on which the fired body was sealed was bonded to a wall perpendicular to the horizon so as to adhere thereto, and then a case in which the fired body did not peel from the SUS304 substrate owing to its own weight even after a lapse of 24 hours, was marked with Symbol “o”, and a case in which the fired body peeled therefrom and fell was marked with Symbol “x”.

As apparent from the tables, Samples Nos. 1 to 17 serving as Examples of the present invention each had a low softening point, and hence were excellent in flowability. In addition, the samples were excellent in weather resistance. Meanwhile, Sample No. 18 serving as a comparative example exceeded the predetermined amount of MgO+CaO+SrO+BaO+ZnO, and hence its glass devitrified during firing and had poor flowability. Sample No. 19 serving as a comparative example exceeded the predetermined amount of the content of MoO₃, and hence did not vitrify. Samples Nos. 20 and 21 serving as comparative examples did not contain MgO, CaO, SrO, BaO, and ZnO, and hence had poor weather resistance.

### INDUSTRIAL APPLICABILITY

The glass composition of the present invention is suitable for sealing of each of a semiconductor integrated circuit, a crystal oscillator, a flat display apparatus, a glass terminal for LED use, and an aluminum nitride substrate. In addition, the glass composition of the present invention may also be used as a sealing material for a metal.

1. A glass composition, comprising, in terms of mol %, 1% to 30% of MgO+CaO+SrO+BaO+ZnO, 30% to 80% of TeO₂, and 5% to 30% of MoO₃.

2. The glass composition according to claim 1, wherein the glass composition comprises, in terms of mol %, 1% to 30% of Li₂O+Na₂O+K₂O, 1% to 30% of MgO+CaO+SrO+BaO+ZnO, 30% to 80% of TeO₂, and 5% to 30% of MoO₃.

3. The glass composition according to claim 1, wherein the glass composition comprises, in terms of mol %, 1% to 30% of Li₂O.

4. The glass composition according to claim 1, wherein the glass composition comprises, in terms of mol %, 1% to 30% of BaO.

5. The glass composition according to claim 1, further comprising, in terms of mol %, 0% to 10% of TiO₂+Al₂O₃.

6. The glass composition according to claim 1, further comprising, in terms of mol %, 1% to 10% of Al₂O₃.

7. The glass composition according to claim 1, further comprising, in terms of mol %, 0% to 30% of CuO, 0% to 20% of WO₃, and 0% to 10% of P₂O₅.

8. The glass composition according to claim 1, further comprising, in terms of mol %, 1% to 30% of CuO.

9. A sealing material, comprising:
40 vol % to 100 vol % of glass powder formed of the glass composition of claim 1; and
0 vol % to 60 vol % of refractory filler powder.

10. The sealing material according to claim 9, wherein the refractory filler powder contains Zr₂WO₄(PO₄)₂.

11. The sealing material according to claim 9, wherein the refractory filler powder has an approximately spherical shape.

12. The sealing material according to claim 9, wherein the sealing material is used for a crystal oscillator package.

13. A sealing material paste, comprising:
the sealing material of claim 9; and
a vehicle.
